(19) United States
(12) Patent Application Publication
(10) Pub. No.: US 2011/0240337 A1
(43) Pub. Date: Oct. 6, 2011

(54) INTERCONNECTS FOR PHOTOVOLTAIC PANELS

(76) Inventors: John Montello, El Cajon, CA (US); Mark Farrelly, Carlsbad, CA (US); Anand Janaswamy, Cardiff, CA (US); Mike Curtis, Temecula, CA (US)

(21) Appl. No.: 12/754,588

(22) Filed: Apr. 5, 2010

(51) Int. Cl. H01B 5/00; H01L 31/048

(52) U.S. Cl. 174/126.1; 136/251

(57) ABSTRACT

Various embodiments of the invention provide an interconnect designed to be placed between layers of a photovoltaic laminate, and that has built-in in-plane stress relief features. In accordance with various embodiments, the interconnect, once implemented into a photovoltaic laminate, can withstand at least 200 temperature cycles, as is required by certain certifying bodies, without suffering failure. According to one embodiment of the present invention, an interconnect is provided for connecting a first photovoltaic cell to the bus array or a second photovoltaic cell within a photovoltaic laminate, the interconnect comprising: a single conductive wire having a cross-section sufficient for placement between layers of a photovoltaic laminate; wherein the single conductive wire comprises a stress-relief feature, and the stress-relief feature enables the interconnect to maintain a connection between the first photovoltaic cell and the bus array or the second photovoltaic cell while absorbing stress induced by a change in position of the first photovoltaic cell relative to a position of the bus array or the second photovoltaic cell.

### FIELD OF THE INVENTION

The present invention relates to apparatuses and methods for solar panels, and more particularly, to apparatuses and methods for interconnects used in conjunction with solar cells (i.e., photovoltaic panels).

### DESCRIPTION OF THE RELATED ART

Solar power is a viable clean and renewable option to producing energy with a virtually unlimited supply. Technological innovations and improvements are generally reducing the costs associated with installing, operating, and maintaining solar power equipment. These solar energy systems typically comprise solar or photovoltaic (PV) cells, which convert energy from the sun or other light source into electrical energy. These PV cells are usually arranged in an array configuration and encapsulated within a PV laminate that is created using layers of materials. Some of those materials include glass and plastic composites, such fiberglass reinforced plastic (FRP). The electricity is drawn from the individual PV cells using bus arrays, also encapsulated within the PV laminate, that connect to leads typically placed on edge of the PV laminate. The PV laminates are placed in PV modules (i.e., panels) that can be installed on roofs of buildings (e.g., homes) for energy generation.

FIG. 1A provides an image of an example PV laminate 10. Referring to FIG. 1, the PV laminate 10 comprises an array of PV cells 13, and a bus array 16 used to draw electricity from the PV cells to the leads 17 located on the edge of the PV laminate 10. The individual PV cells 13 are connected to the bus array 16 using interconnects located at either the top or bottom of the each PV cell 13. Section 19 highlights an area having such interconnects. FIG. 1B provides an image of typical interconnects 21, these specifically connecting PV cell 24 front-to-back with PV cell 23.

Conventional interconnects are known to suffer from fatigue that results in their breaking due to differential thermal expansion of the materials used in the laminate. PV laminates usually comprise materials having coefficients of thermal expansion (CTE) that are different with respect to one another. When this difference is significant enough, the coefficient mismatch causes a substantial amount of stress on the interconnects within the PV laminate, eventually causing them to fail (e.g., “opening” up of the wire making up the interconnect). Such occurrences have been observed with respect to PV laminates subjected to thermal cycling (TC). For example, such an occurrence can be observed for a PV laminate sample comprising an aluminum back sheet.

Generally, PV cells are encapsulated in glass, which has a coefficient of thermal expansion that is very low, leading to a low coefficient mismatch between the glass and the PV cells. However, other materials used for the back sheet of the PV laminate have a coefficient that is higher than that of glass, which results in interconnect failure.

### BRIEF SUMMARY OF EMBODIMENTS OF THE INVENTION

According to various embodiments of the invention, interconnects are provided, designed to be placed between layers of a photovoltaic (PV) laminate (i.e., in-plane) comprising photovoltaic (PV) cells, and designed to have built-in stress relief features, or sections, that compensate for stress from movement of the cells with respect to other components within the laminate. Additionally, in some embodiments, the interconnect is made of a single conductive wire, capable of being placed in one plane. In accordance with various embodiments of the present invention, the interconnect, once implemented into a photovoltaic laminate, can withstand at least repeated temperature cycles, for an extended period of time, without suffering failure (e.g., breakage). Such repeated temperature cycles are commonly performed under testing standards for photovoltaic products.

One embodiment of the present invention provides an interconnect for connecting a first photovoltaic cell to a bus array or a second photovoltaic cell within a photovoltaic laminate, comprising: a single conductive wire having a cross-section sufficient for placement between layers of a photovoltaic laminate; and a solder coating covering the conductive wire; wherein the single conductive wire comprises a stress-relief feature, and the stress-relief feature enables the interconnect to maintain a connection between the first photovoltaic cell and the bus array or the second photovoltaic cell while absorbing stress induced by a change in position of the first photovoltaic cell relative to a position of the bus array or the second photovoltaic cell. This change in position may be caused, for example, by the thermal expansion of materials within the photovoltaic laminate. It should be noted that a first photovoltaic cell can be connected to a bus array either by directly connecting it to the bus array using an interconnect, or by using an interconnect to connect it to another photovoltaic cell (i.e., a second photovoltaic cell) that is directly or indirectly connected to the bus array.

In some embodiments, the in plane stress-relief feature is a geometric shape that allows for extension or compression of the interconnect within photovoltaic laminate caused by the change in position of the first photovoltaic cell relative to the position of the bus array or the second photovoltaic cell. Example geometric shapes include, but are not limited to, a U-shape, S-shape, V-shape, and Ω-shape. After reading this description, one of ordinary skill in the art would be able to contemplate other geometric shapes that would also be suitable.

For particular embodiments, the in plane stress-relief feature may comprise a physical configuration different from that of the remainder of the conductive wire. For example, the stress-relief feature may have a braided configuration (i.e., the stress relief feature is a braided conductive wire). Also, for some embodiments, the single conductive wire may be made of copper, a copper alloy, or some other conductive material used in photovoltaic laminates, and the solder coating may be a Sn/Pb/Ag solder alloy (e.g., 62% Sn/36% Ag/2% Pb).

In some embodiments, the single conductive wire may have a cross-section measuring, for example, 0.15-0.2 mm in thickness and 1.6-1.8 mm in width. In other embodiments, the solder coating is of sufficient thickness for use in the photovolatic laminate. For example, the thickness of the solder coating may be 15 μm. As would be appreciated by those of ordinary skill in the art, many other dimensional characteristics are possible without departing from the scope of the invention.

Other features and aspects of the invention will become apparent from the following detailed description, taken in conjunction with the accompanying drawings, which illustrate, by way of example, the features in accordance with embodiments of the invention. The summary is not intended to limit the scope of the invention, which is defined solely by the claims attached hereto.

### BRIEF DESCRIPTION OF THE DRAWINGS

The present invention, in accordance with one or more various embodiments, is described in detail with reference to the following figures. The drawings are provided for purposes of illustration only and merely depict typical or example embodiments of the invention. These drawings are provided to facilitate the reader's understanding of the invention and shall not be considered limiting of the breadth, scope, or applicability of the invention. It should be noted that for clarity and ease of illustration these drawings are not necessarily made to scale.

Some of the figures included herein illustrate various embodiments of the invention from different viewing angles. Although the accompanying descriptive text may refer to such views as “top,” “bottom” or “side” views, such references are merely descriptive and do not imply or require that the invention be implemented or used in a particular spatial orientation unless explicitly stated otherwise.

FIG. 1A is an image of an example photovoltaic laminate that may utilize interconnects in accordance with embodiments of the present invention.

FIG. 1B is an image of example interconnects connecting two photovoltaic cells on a photovoltaic laminate.

FIGS. 2-4 are diagrams illustrating example interconnects in accordance with embodiments of the present invention.

FIG. 5 is an image of example interconnects in accordance with an embodiment of the present invention.

FIG. 6A is an image of example interconnects in accordance with embodiments.

FIG. 6B is an image providing a back view of the photovoltaic cells and interconnects depicted in FIG. 6A.

FIG. 7 is an image of an interconnect in accordance with an embodiment of the present invention.

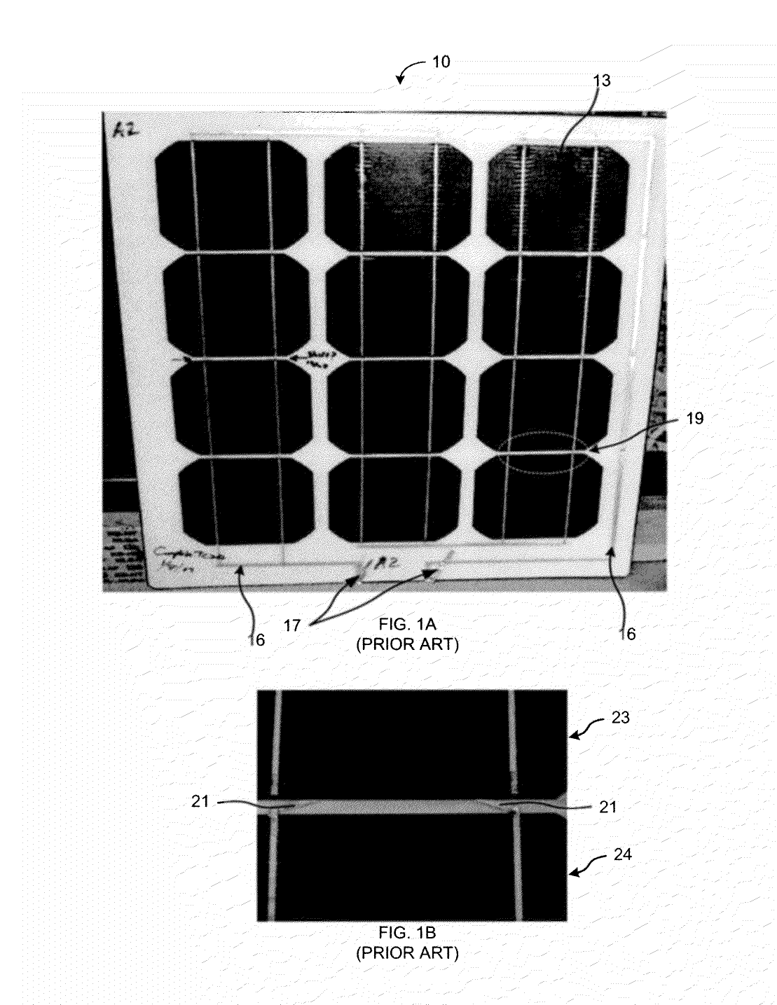

The figures are not intended to be exhaustive or to limit the invention to the precise form disclosed. It should be understood that the invention can be practiced with modification and alteration, and that the invention be limited only by the claims and the equivalents thereof.

### DETAILED DESCRIPTION OF THE EMBODIMENTS OF THE INVENTION

The present invention is directed toward interconnects designed to be placed between layers of a photovoltaic (PV) laminate (i.e., in-plane), and that have one or more built-in stress relief features or sections capable of compensating for stresses subjected on the interconnects.

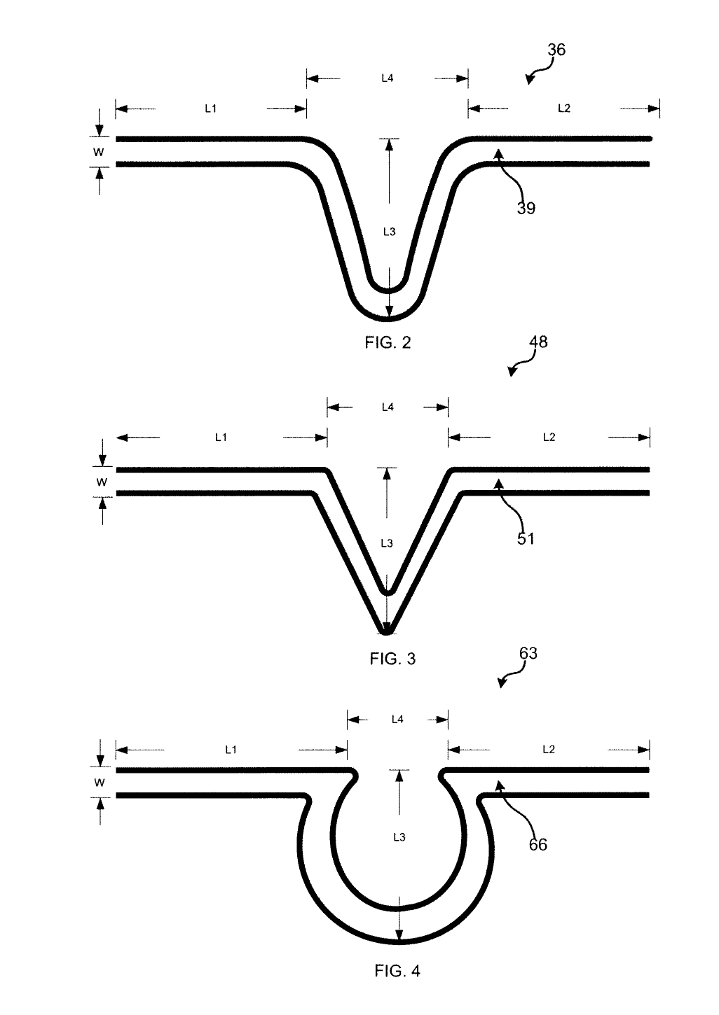

Referring now to the drawings and more particularly to FIGS. 2-4, illustrated are example interconnects in accordance with embodiments of the present invention. Specifically, FIGS. 2-4 depict interconnects where the stress-relief feature comprises a geometric shape, designed to compensate for movement of a PV cell toward or away from its connection point. FIG. 2 depicts an interconnect 36 having a “U” geometric shape, FIG. 3 depicts an interconnect 48 having a “V” geometric shape, and FIG. 4 depicts an interconnect 53 having a “Ω” geometric shape. An alternative geometric shape not shown is an “S” geometric shape.

The depicted interconnects are made of a conductive material and coated with solder coating, allowing for easy connections. In addition, the physical dimensions of each interconnect is configured to make the interconnect suitable for in-plane placement within the PV laminate. For example, the cross-section dimensions for the interconnect 36 of FIG. 2 may be 1.7 mm for the width (W) and 0.19 mm for the thickness. With respect to the other dimensions of the interconnect 36, 48 and 63, L1-L4 can be made to fit any geometry suitable for allowing the interconnect to be placed in-plane and function between photovoltaic cells.

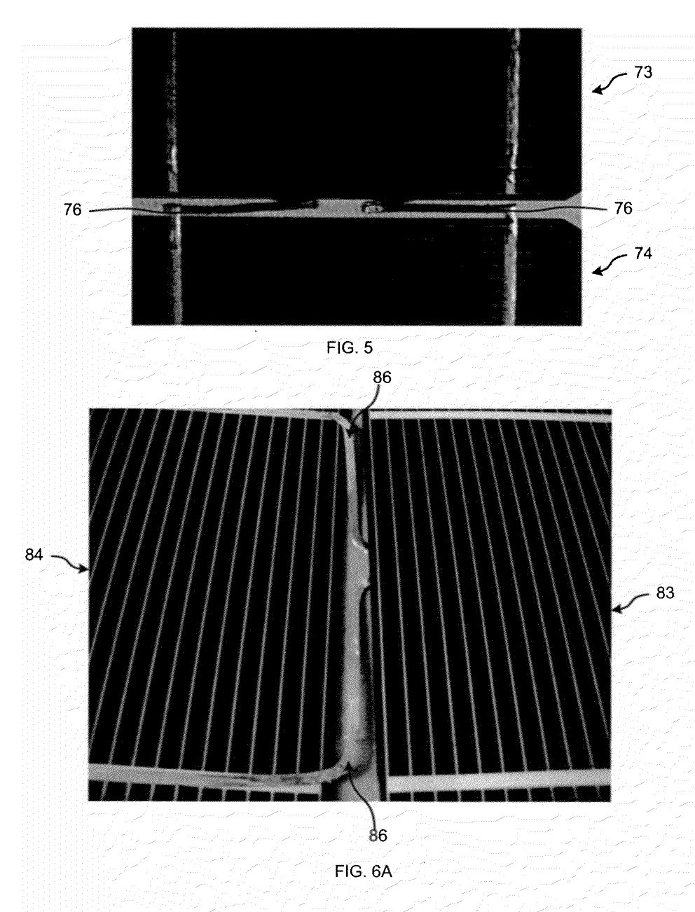

Referring now to FIG. 5, an image is provided of example interconnects 76 in accordance with an embodiment of the present invention. Specifically, depicted are interconnects having a “U” geometric shape, connecting PV cell 74 front-to-back with PV cell 73, in a completed PV laminate.

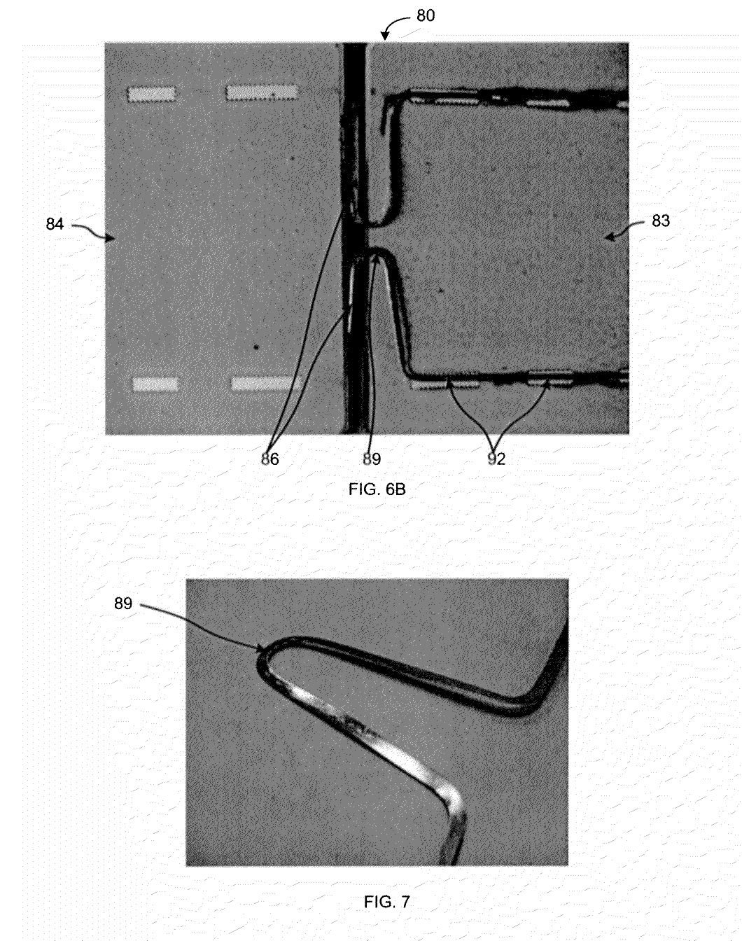

FIG. 6 provides an image of other U-shape interconnects 86 in accordance with an embodiment of the present invention. Like interconnects 76 of FIG. 5, interconnects 86 connect PV cell 84 front-to-back with PV cell 83. However, the interconnects depicted are shown before completion of the PV laminate. The image of FIG. 6B provides a back view of the PV cells (83 and 84) and interconnects 86 depicted in FIG. 6A. FIG. 6B depicts how interconnects 86 connect to back contact points 92 of PV cell 83. The interconnects 86 connect from the backside of one PV cell to the top and front of an adjacent PV cell. Each of the interconnects 86 comprise a U-shape stress-relief feature 89, designed to compensate for change in position of PV cell 84 relative to the position of PV cell 83 once the PV cells (83 and 84) are encapsulated in a PV laminate (not shown), without breakage (i.e., maintaining a connection between a PV cell and the bus array or a second PV cell). As described earlier, such position changes of PV cells can be attributed to, among other things, the thermal expansion of materials utilized in the creation of the PV laminate. FIG. 7 provides an image having a close view of one of the interconnects 86 utilized in FIGS. 6A and 6B.

While various embodiments of the present invention have been described above, it should be understood that they have been presented by way of example only, and not of limitation. Likewise, the various diagrams may depict an example architectural or other configuration for the invention, which is done to aid in understanding the features and functionality that can be included in the invention. The invention is not restricted to the illustrated example architectures or configurations, but the desired features can be implemented using a variety of alternative architectures and configurations. Indeed, it will be apparent to one of skill in the art how alternative functional, logical or physical partitioning and configurations can be implemented to implement the desired features of the present invention. Also, a multitude of different constituent module names other than those depicted herein can be applied to the various partitions. Additionally, with regard to flow diagrams, operational descriptions and method claims, the order in which the steps are presented herein shall not mandate that various embodiments be implemented to perform the recited functionality in the same order unless the context dictates otherwise.

Although the invention is described above in terms of various exemplary embodiments and implementations, it should be understood that the various features, aspects and functionality described in one or more of the individual embodiments are not limited in their applicability to the particular embodiment with which they are described, but instead can be applied, alone or in various combinations, to one or more of the other embodiments of the invention, whether or not such embodiments are described and whether or not such features are presented as being a part of a described embodiment. Thus, the breadth and scope of the present invention should not be limited by any of the above-described exemplary embodiments.

Terms and phrases used in this document, and variations thereof, unless otherwise expressly stated, should be construed as open ended as opposed to limiting. As examples of the foregoing: the term “including” should be read as meaning “including, without limitation” or the like; the term “example” is used to provide exemplary instances of the item in discussion, not an exhaustive or limiting list thereof; the terms “a” or “an” should be read as meaning “at least one,” “one or more” or the like; and adjectives such as “conventional,” “traditional,” “normal,” “standard,” “known” and terms of similar meaning should not be construed as limiting the item described to a given time period or to an item available as of a given time, but instead should be read to encompass conventional, traditional, normal, or standard technologies that may be available or known now or at any time in the future. Likewise, where this document refers to technologies that would be apparent or known to one of ordinary skill in the art, such technologies encompass those apparent or known to the skilled artisan now or at any time in the future.

The presence of broadening words and phrases such as “one or more,” “at least,” “but not limited to” or other like phrases in some instances shall not be read to mean that the narrower case is intended or required in instances where such broadening phrases may be absent. The use of the term “module” does not imply that the components or functionality described or claimed as part of the module are all configured in a common package. Indeed, any or all of the various components of a module, whether control logic or other components, can be combined in a single package or separately maintained and can further be distributed in multiple groupings or packages or across multiple locations.

Additionally, the various embodiments set forth herein are described in terms of exemplary block diagrams, flow charts and other illustrations. As will become apparent to one of ordinary skill in the art after reading this document, the illustrated embodiments and their various alternatives can be implemented without confinement to the illustrated examples. For example, block diagrams and their accompanying description should not be construed as mandating a particular architecture or configuration.

What is claimed is:

1. An interconnect for connecting a first photovoltaic cell to a bus array or a second photovoltaic cell within a photovoltaic laminate, comprising:
a single conductive wire having a cross-section sufficient for placement between layers of a photovoltaic laminate; and
a solder coating covering the conductive wire;
wherein the single conductive wire comprises a stress-relief feature, and the stress-relief feature enables the interconnect to maintain a connection between the first photovoltaic cell and the bus array or the second photovoltaic cell while absorbing stress induced by a change in position of the first photovoltaic cell relative to a position of the bus array or the second photovoltaic cell.

2. The interconnect of claim 1, wherein the change in position is caused by the thermal expansion of materials within the photovoltaic laminate.

3. The interconnect of claim 1, wherein the stress-relief feature is a geometric shape that allows for extension or compression of the interconnect within photovoltaic laminate caused by the change in position of the first photovoltaic cell relative to the position of the bus array or the second photovoltaic cell.

4. The interconnect of claim 3, wherein the geometric shape is a U-shape, S-shape, V-shape, or Ω-shape.

5. The interconnect of claim 1, wherein the stress-relief feature comprises a braided conductive wire.

6. The interconnect of claim 1, wherein the solder coating is a Sn/Pb/Ag solder alloy.

7. The interconnect of claim 1, wherein the solder coating is of sufficient thickness for use in the photovoltaic laminate.

8. The interconnect of claim 1, wherein the single conductive wire is made of copper, or a copper alloy.
